(19) United States
(12) Patent Application Publication
(10) Pub. No.: US 2024/0288392 A1
(43) Pub. Date: Aug. 29, 2024

(54) SENSOR FAULT DIAGNOSIS METHOD, APPARATUS, ELECTRONIC DEVICE AND STORAGE MEDIUM

(71) Applicant: China Agricultural University, Beijing (CN)

(72) Inventors: Daoliang Li, Beijing (CN); Xianbao Xu, Beijing (CN); Cong Wang, Beijing (CN); Zhuangzhuang Bai, Beijing (CN); Chuanyu Sun, Beijing (CN)

(21) Appl. No.: 18/417,890

(22) Filed: Jan. 19, 2024

(30) Foreign Application Priority Data
Feb. 22, 2023 (CN) 2023101508496

(51) Int. Cl. G01N 27/02; G01N 27/416; G01R 27/26

(52) U.S. Cl. CPC G01N 27/028; G01N 27/4163; G01R 27/26

(57) ABSTRACT

The disclosure provides a sensor fault diagnosis method, an apparatus, an electronic device and a storage medium. The method comprises: determining target concentration of electrolyte in a sensor at time t; determining residual concentration based on initial concentration and the target concentration of the electrolyte; acquiring an impedance value and determining a concentration measurement value based on the impedance value and correlation information between concentration and the impedance; determining fault information of the sensor based on the residual concentration and the concentration measurement value. The concentration of the electrolyte is estimated by using an impedance calibrating method in combination with theoretical calculation, and the sensor fault diagnosis is realized by establishing a difference comparison interval between the concentration measurement value and a theoretical calculation value of the electrolyte, thereby saving the cost of fault diagnosis and improving the accuracy of fault diagnosis.

### CROSS-REFERENCE TO RELATED APPLICATION

This patent application claims the benefit and priority of Chinese Patent Application No. 202310150849.6 filed with the China National Intellectual Property Administration on Feb. 22, 2023, the disclosure of which is incorporated by reference herein in its entirety as part of the present application.

### TECHNICAL FIELD

The present disclosure relates to the technical field of fault diagnosis, in particular to a sensor fault diagnosis method, an apparatus, an electronic device and a storage medium.

### BACKGROUND

At present, sensor fault diagnosis mainly uses two methods. One method is a hardware redundancy method, in which several redundant sensors measure the same parameter and generate residuals which contain important fault information, and sensor fault detection can be carried out by comparing the residuals with thresholds. The other method is an analytical redundancy method, including a model-based diagnosis method, a knowledge-based diagnosis method and a data-driven diagnosis method. However, the above fault diagnosis methods have the following shortcomings.

(1) The hardware redundancy method needs to use a plurality of sensors, which complicates the structure and increases the weight and cost of the system.

(2) The analytical redundancy method requires a lot of data support or prior models. The model-based diagnosis method needs a high-precision model, but it is difficult to establish an accurate mathematical model for sensors in a nonlinear system. The knowledge-based sensor diagnosis method needs a lot of historical measurement data. In the sensor fault diagnosis system, the reasoning knowledge in the diagnosis process is mostly expressed in the form of If-Then rules. The online diagnosis process infers the working state according to the observed data facts, but this method can only diagnose according to the existing rules and cannot identify and further explain new faults. The data-driven method needs to extract fault features in the process of processing, and improper fault feature extraction will have a great impact on detection.

Thus, how to realize sensor fault diagnosis is an urgent problem to be solved.

### SUMMARY

The present disclosure provides a sensor fault diagnosis method, an apparatus, an electronic device and a storage medium, which intends to solve the problem of sensor fault diagnosis. The sensor fault diagnosis is realized by estimating the concentration of the electrolyte using an impedance calibrating method in combination with theoretical calculation, and establishing a difference comparison interval between the concentration measurement value and a theoretical calculation value of the electrolyte, so that the cost of fault diagnosis is saved and the accuracy of fault diagnosis is improved.

The present disclosure provides a sensor fault diagnosis method, including:
determining target concentration of electrolyte in a sensor at time t;
determining residual concentration of the electrolyte based on initial concentration and the target concentration of the electrolyte;
acquiring an impedance value of the electrolyte, and determining a concentration measurement value of the electrolyte based on the impedance value and correlation information between concentration and an impedance of the electrolyte; and
determining fault information of the sensor based on the residual concentration and the concentration measurement value of the electrolyte.

In one embodiment, determining the fault information of the sensor based on the residual concentration and the concentration measurement value of the electrolyte includes:
determining a difference between the residual concentration and the concentration measurement value of the electrolyte;
determining that the sensor has a fault if the difference is greater than a first threshold value; and
determining an interval measurement difference of the concentration of the electrolyte and determining a fault level of the sensor based on the interval measurement difference.

In one embodiment, determining the fault level of the sensor based on the interval measurement difference includes:
determining that the fault level of the sensor is level 1 if the interval measurement difference is greater than a second threshold;
determining that the fault level of the sensor is level 2 if the interval measurement difference is greater than a third threshold and less than the second threshold; and
determining that the fault level of the sensor is level 3 if the interval measurement difference is greater than a fourth threshold and less than the third threshold.

In one embodiment, determining the target concentration of the electrolyte in the sensor at time t includes:
determining the total number of electrons in a reaction system corresponding to the electrolyte; and
determining the target concentration of the electrolyte in the sensor at time t based on the total number of electrons, the initial concentration, initial volume of the electrolyte, molar mass of water and density of water.

The calculation formulas of the target concentration of the electrolyte in the sensor at time t are as follows:

$$\{ \begin{matrix}N = \int \frac{1}{e} . {I}_{t} . d t \\ {C}_{b} = \frac{{C}_{a} . {V}_{a} - N}{{V}_{a} - \frac{N . M}{2 ρ}}\end{matrix} ,$$

where N represents the total number of electrons in the reaction system, e represents an elementary charge, Iₜ represents a current value at time t, Cₐ represents initial concentration, C_{b} represents target concentration of the electrolyte at time t, Vₐ represents the initial volume of the electrolyte, M represents the molar mass of water, and β represents the density of water.

In one embodiment, after determining the residual concentration of the electrolyte based on the initial concentration and the target concentration of the electrolyte, the method further includes:
determining a reaction rate of the electrolyte; and
determining the residual service life of the sensor based on the reaction rate, the residual concentration and the initial concentration of the electrolyte.

The calculation formulas of the residual service life of the sensor are as follows:

$$\{ \begin{matrix}L = \frac{{C}_{y}}{{k}_{v} {C}_{a}} \\ {k}_{v} = Co * {Ke}_{1}^{\frac{- Δ G}{RT}} * {K}_{Δ k} \\ {K}_{Δ k} = \frac{Δφ}{Δχ}\end{matrix} ,$$

where L represents the residual service life of the sensor, C_{y} represents the residual concentration of the electrolyte, Cₐ represents the initial concentration, kᵥ represents the reaction rate, Co represents dissolved oxygen concentration, K represents a pre-exponential factor of a chemical reaction, e₁ represents a constant, R represents a molar gas constant, T represents a reaction temperature, ΔG represents activation energy, K_{Δk} represents a fault reaction rate, Δφ represents an interval measurement difference, and Δχ represents a first threshold.

In one embodiment, the target temperature is determined by the following steps:
acquiring a temperature value of the sensor; and
acquiring the correlation information between the concentration and the impedance of the electrolyte based on the temperature value.

In one embodiment, the method further includes:
determining a sum value between the difference and a measurement error; and
calibrating the sensor based on the difference if the sum value is greater than a tolerance deviation value and less than the first threshold value.

The present disclosure further provides a sensor fault diagnosis apparatus, including: a channel switching circuit, a current to voltage measuring module and an impedance measuring module.

The channel switching circuit is configured to control switching the current to voltage acquisition module and the impedance measuring module.

The current to voltage measuring module is configured to measure a current value corresponding to dissolved oxygen of the electrolyte.

The impedance measuring module is configured to measure the impedance value of the electrolyte.

The present disclosure further provides an electronic device, including a memory, a processor and a computer program stored in the memory, which can be executed on the processor, and when the computer program is executed, the processor implements the sensor fault diagnosis method described in any one of the above.

The present disclosure further provides a non-transient computer-readable storage medium on which a computer program is stored, wherein the computer program, when executed by a processor, implements the sensor fault diagnosis method described in any one of the above.

The present disclosure provides a sensor fault diagnosis method, an apparatus, an electronic device and a storage medium. The method includes: determining target concentration of electrolyte in a sensor at time t; determining residual concentration of the electrolyte based on initial concentration and the target concentration of the electrolyte; acquiring an impedance value of the electrolyte, and determining a concentration measurement value of the electrolyte based on the impedance value and correlation information between the concentration and the impedance of the electrolyte; determining fault information of the sensor based on the residual concentration and the concentration measurement value of the electrolyte. According to the present disclosure, the sensor fault diagnosis is realized by estimating the concentration of the electrolyte using an impedance calibrating method in combination with theoretical calculation, and establishing a difference comparison interval between the concentration measurement value and a theoretical calculation value of the electrolyte, so that the cost of fault diagnosis is saved and the accuracy of fault diagnosis is improved.

### BRIEF DESCRIPTION OF THE DRAWINGS

In order to explain the technical scheme of the present disclosure or the prior art more clearly, the drawings required in the description of the embodiments or the prior art will be briefly introduced hereinafter. Obviously, the accompanying drawings in the following description are some embodiments of the present disclosure, and other drawings can be obtained according to these drawings without creative efforts for those skilled in the art.

FIG. 1 is a first schematic flow chart of a sensor fault diagnosis method according to the present disclosure.

FIG. 2 is a second schematic flow diagram of a sensor fault diagnosis method according to the present disclosure.

FIG. 3 is a schematic structural diagram of a sensor fault diagnosis apparatus according to the present disclosure.

FIG. 4 is a schematic structural diagram of an electronic device according to the present disclosure.

### DETAILED DESCRIPTION OF THE EMBODIMENTS

In order to make the purpose, technical scheme and advantages of the present disclosure clearer, the technical scheme in the present disclosure will be described clearly and completely with reference to the accompanying drawings hereinafter. Obviously, the described embodiments are some embodiments of the present disclosure, rather than all of the embodiments. Based on the embodiments in the present disclosure, all other embodiments obtained by those skilled in the art without creative efforts shall fall within the scope of protection of the present disclosure.

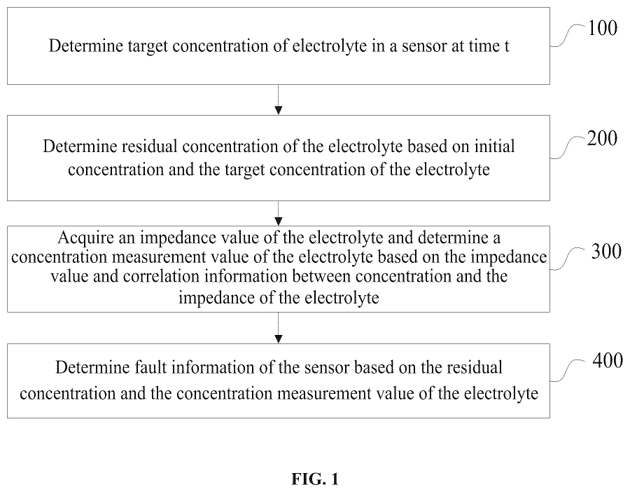

Hereinafter, the sensor fault diagnosis method, the apparatus, the electronic device and the storage medium of the present disclosure will be described with reference to FIGS. 1 to 4.

Specifically, the present disclosure provides a sensor fault diagnosis method. Referring to FIG. 1, FIG. 1 is a first schematic flow chart of a sensor fault diagnosis method according to the present disclosure.

The sensor fault diagnosis method provided by an embodiment of the present disclosure includes steps 100-400.

In step 100, target concentration of electrolyte in a sensor at time t is determined.

It should be noted that the embodiment of the present disclosure is mainly applied to a dissolved oxygen sensor, wherein the dissolved oxygen sensor is a sensing device for measuring the amount of dissolved oxygen in water.

The embodiment of the present disclosure realizes the fault diagnosis, self-calibration and life prediction of the electrolyte in the dissolved oxygen sensor based on the measurement signal and theoretical calculation, rather than requires a large amount of data for modeling on the fault diagnosis and life prediction of the sensor.

It should be further noted that according to Faraday's law, the magnitude of current is proportional to the number of electrons, and the number of electrons per unit time can be calculated based on the relationship between the circuit current, the voltage and the charge. The total number of electrons flowing through the circuit during a period of time can be obtained by integrating the current during this period of time.

According to the principle of chemical reaction, based on the principle of chemical reaction equilibrium, there is a relationship between the number of transferred electrons and the number of electrons generated from molecular or ion conversion. Through the chemical reaction equation, the relationship between the number of electrons and the number of electrons generated from molecular or ion conversion can be constructed, so as to obtain the number of reactants or products participating in the reaction.

The electrolyte mainly provides ions for the dissolved oxygen electrode reaction. When the initial concentration of the electrolyte is known, it is necessary to determine the target concentration of the electrolyte in the sensor at time t to deduce the concentration of the residual ions in the electrolyte.

Determining the target concentration of electrolyte in the sensor at time t specifically includes: determining the total number of electrons in a reaction system corresponding to the electrolyte; and then determining the target concentration of the electrolyte in the sensor at time t based on the total number of electrons, the initial concentration, initial volume of the electrolyte, molar mass of water and density of water.

The calculation formulas of the target concentration of the electrolyte in the sensor at time t are as follows:

$$\{ \begin{matrix}N = \int \frac{1}{e} . {I}_{t} . dt \\ {C}_{b} = \frac{{C}_{a} . {V}_{a} - N}{{V}_{a} - \frac{N . M}{2 ρ}}\end{matrix} ,$$

where N represents the total number of electrons in the reaction system, e represents an elementary charge, Iₜ represents a current value at time t, Cₐ represents the initial concentration, C_{b} represents the target concentration of the electrolyte at time t, Vₐ represents the initial volume of the electrolyte, M represents the molar mass of water, and ρ represents the density of water.

It should be further noted that the sensor fault diagnosis apparatus is provided with a current to voltage measuring module. The current value corresponding to dissolved oxygen in the electrolyte can be measured using the current to voltage measuring module, i.e., the current value of dissolved oxygen in the electrolyte at time t, that is, Iₜ is measured.

According to the embodiment of the present disclosure, the total number of electrons in the reaction system is obtained by integrating time and current, and then the target concentration of the electrolyte at time t is determined based on information such as the total number of electrons, the initial concentration, the initial volume of the electrolyte and the like. Based on this, the accuracy of determining the electrolyte is improved, and the accuracy of sensor fault diagnosis is further improved.

In step 200, residual concentration of the electrolyte is determined based on the initial concentration and the target concentration of the electrolyte.

After determining the target concentration of the electrolyte at time t, the residual concentration of the electrolyte is determined based on the initial concentration and the target concentration of the electrolyte.

The residual concentration of the electrolyte is related to the degree of chemical reaction. In the process of chemical reaction, the number of reaction electrons is equal to the number of consumed chloride ions, and the reaction consumes water molecules. Based on this, the residual concentration of the electrolyte can be derived from the current value, and the specific formulas are as follows:

$$\{ \begin{matrix}N = \int \frac{1}{e} \cdot {I}_{t} \cdot dt \\ {C}_{y} = {C}_{a} - {C}_{b} = {C}_{a} - \frac{{C}_{a} \cdot {V}_{a} - N}{{V}_{a} - \frac{N \cdot M}{2 ρ}}\end{matrix} ,$$

where N represents the total number of electrons in the reaction system, e represents the elementary charge, Iₜ represents the current value at time t, C_{y} represents residual concentration of the electrolyte, Cₐ represents the initial concentration, C_{b} represents the target concentration of the electrolyte at time t, Vₐ represents the initial volume of the electrolyte, M represents the molar mass of water, and ρ represents the density of water.

In step 300, an impedance value of the electrolyte is acquired and a concentration measurement value of the electrolyte is determined based on the impedance value and correlation information between the concentration and the impedance of the electrolyte.

It should be noted that before determining the concentration measurement value of the electrolyte, it is required to calibrate the relationship curve between the concentration and the impedance of the electrolyte, that is, to determine the correlation information between the concentration and the impedance of the electrolyte.

It can be known from the reaction equation of a polarographic dissolved oxygen sensor that the reaction will consume chloride ions and water. According to the reaction equation, the corresponding impedances at different concentrations and volumes are measured, respectively. The relationship curve between the residual concentration C, and the impedance Z of the electrolyte is established: Z∝C_{y}.

The reaction equation is as follows:

O₂+H₂O+4Ag+4KCl→4AgCl+4KOH,

where O₂ represents oxygen, H₂O represents water molecules, Ag represents silver, KCl represents potassium chloride, AgCl represents silver chloride, KOH represents potassium hydroxide.

It should be further noted that the sensor fault diagnosis apparatus is provided with an impedance measuring module which can measure the impedance value of the electrolyte. The impedance value of the electrolyte measured by the impedance measuring module is acquired, and then the concentration measurement value of the electrolyte is determined based on the correlation information between the concentration and the impedance of the electrolyte and the measured impedance value.

Refer to Table 1, which shows the correlation information between the concentration and the impedance of the electrolyte:

TABLE 1

| concentration of electrolyte | impedance |
|---|---|
| 20 mg/L | AΩ |
| 30 mg/L | BΩ |
| 40 mg/L | CΩ |
| 50 mg/L | DΩ |
| 60 mg/L | EΩ |

As it can be seen from Table 1, assuming that the measured impedance value is BΩ, it can be determined that the concentration measurement value of the electrolyte is 30 mg/L.

In step 400, fault information of the sensor is determined based on the residual concentration and the concentration measurement value of the electrolyte.

After determining the residual concentration and the concentration measurement value of the electrolyte, the fault information of the sensor is determined based on the residual concentration and concentration measurement value of the electrolyte, wherein the fault information includes information such as the fault type, the fault level, etc. For example, the difference between the residual concentration and the concentration measurement value of the electrolyte is determined, different difference comparison intervals are established, and the fault level of the sensor is determined based on the difference comparison interval.

According to the embodiment of the present disclosure, the change of the electrolyte of the sensor is determined according to the alternating current impedance characteristics of the electrolyte, and the loss of the electrolyte will lead to the change of the volume of the electrolyte and the ion concentration of the electrolyte. By establishing the quantitative relationship curve between the concentration and the impedance of the electrolyte, the ion concentration, that is, the concentration measurement value, can be obtained in the case of measuring the impedance of the electrolyte, and then the detection calculation result (that is, the concentration measurement value) is compared with the theoretical calculation value (the residual concentration of the electrolyte), so as to determine whether the electrolyte is lost and the severity of the loss to determine fault information of the sensor.

The present disclosure provides a sensor fault diagnosis method, including: determining target concentration of electrolyte in a sensor at time t; determining residual concentration of the electrolyte based on initial concentration and the target concentration of the electrolyte; acquiring an impedance value of the electrolyte and determining a concentration measurement value of the electrolyte based on the impedance value and correlation information between the concentration and the impedance of the electrolyte; determining fault information of the sensor based on the residual concentration and the concentration measurement value of the electrolyte. According to the embodiment of the present disclosure, the concentration of the electrolyte is estimated by using an impedance calibrating method in combination with theoretical calculation, and the sensor fault diagnosis is realized by establishing a difference comparison interval between the concentration measurement value and a theoretical calculation value of the electrolyte, so that the cost of fault diagnosis is saved and the accuracy of fault diagnosis is improved.

Based on the above embodiment, determining fault information of the sensor based on the residual concentration and the concentration measurement value of the electrolyte includes: determining a difference between the residual concentration and the concentration measurement value of the electrolyte; if the difference is greater than a first threshold value, determining that the sensor has a fault; determining an interval measurement difference of the concentration of the electrolyte to determine a fault level of the sensor based on the interval measurement difference.

It should be noted that under normal working conditions, the concentration of the electrolyte is related to the degree of reaction. When the solution membrane of the sensor is damaged or the sensor housing is broken, the electrolyte will be lost. The loss of electrolyte varies with the degree of damage. If the damage is serious, the electrolyte solution will be lost rapidly, and the impedance of the electrolyte will suddenly increase or decrease. If the damage is not serious, the impedance of the electrolyte will tend to increase or decrease rapidly in a period of time. Based on this, the electrolyte solution loss can be qualitatively analyzed by comparing the difference between the theoretical calculation value and the measurement value of the electrolyte.

The difference between the residual concentration and the concentration measurement value of the electrolyte is determined. If the difference is greater than the first threshold, it indicates that the sensor has a fault, and then an interval measurement difference of the concentration of the electrolyte is determined and a fault level of the sensor is determined based on the interval measurement difference.

The interval measurement difference refers to measuring the concentration of the electrolyte for many times to obtain a plurality of concentration measurement values, then determining the difference between every two concentration measurement values, and finally taking the average value of differences as the interval measurement difference. For example, assuming that the concentration of the electrolyte is measured at intervals for three times, and three concentration measurement values are obtained, namely β₁, β₂ and β₃, the calculation formula of the interval measurement difference Δφ is:

$$Δφ = \frac{( {β}_{1} - {β}_{2} ) + ( {β}_{1} - {β}_{3} ) + ( {β}_{2} - {β}_{3} )}{3} .$$

If the interval measurement difference is greater than a second threshold, it is determined that the fault level of the sensor is level 1; if the interval measurement difference is greater than a third threshold and less than the second threshold, it is determined that the fault level of the sensor is level 2; if the interval measurement difference is greater than a fourth threshold and less than the third threshold, it is determined that the fault level of the sensor is level 3.

The magnitude between the thresholds is: the second threshold>the third threshold>the fourth threshold; and the magnitude between the levels is: level 1>level 2>level 3. The higher the level, the more serious the fault, that is, the more serious the loss of the electrolyte.

For example, it is assumed that the residual concentration (i.e., the theoretical calculation value) of the electrolyte is expressed by α, the concentration measurement value is expressed by β, the first threshold value is expressed by Δχ, the second threshold value is expressed by Δq, the third threshold value is expressed by Δy, and the fourth threshold value is expressed by Δz.

Under normal conditions, the absolute value of the difference between the theoretical calculation value α and the measurement value β of the electrolyte is less than Δχ. If the situation is not satisfied, it is determined that the sensor has a fault, and then the interval measurement is carried out for three times. If the interval measurement difference Δφ is greater than Δq, it is determined that the electrolyte has a fault of complete loss. If the interval measurement difference is greater than Δy and less than Δq, it is determined that the electrolyte has a fault of serious loss. If the interval measurement difference is greater than Δz and less than Δy, it is determined that the electrolyte has a fault of slow loss.

Refer to Table 2, which shows the fault information and determination conditions of the sensor:

TABLE 2

| | | | fault |
|---|---|---|---|
| diagnostic basis | | fault condition | level |
| \|α − β\| < Δχ | | normal | no |
| \|α − β\| > Δχ | Δφ > Δq | the electrolyte lost completely | I |
| | Δy < Δφ < Δq | fault of serious loss | II |
| | Δz < Δφ < Δy | fault of slow loss | III |

According to the embodiment of the present disclosure, the sensor fault diagnosis is realized by establishing a difference comparison interval between the concentration measurement value of the electrolyte and the theoretical calculation value, so that the cost of fault diagnosis is saved and the accuracy of fault diagnosis is improved.

Based on the above embodiment, after determining the residual concentration of the electrolyte based on the initial concentration and the target concentration of the electrolyte, the method further includes: determining a reaction rate of the electrolyte; determining the residual service life of the sensor based on the reaction rate, the residual concentration and the initial concentration of the electrolyte.

It should be noted that the embodiment of the present disclosure intends to estimate the residual service life of the sensor. The relationship between the residual ion concentration and the residual service life of the sensor is established based on the residual ion concentration of the electrolyte according to the combined analysis of the theoretical calculation value and the actual measurement value of the concentration of the electrolyte in the case of determining that there is no electrolyte loss fault, so as to predict the residual service life of the electrolyte and the sensor. The residual service life of the electrolyte corresponds to the residual service life of the sensor. That is, if the residual service life of the electrolyte is short, the residual service life of the sensor is also short; and if the residual service life of the electrolyte is long, the residual service life of the sensor is also long.

The reaction rate of the electrolyte is determined, and then the residual service life of the sensor is determined based on the reaction rate, the residual concentration and the initial concentration of the electrolyte. For example, under normal working conditions, the residual service life of the electrolyte is related to the degree of reaction, and the service life under fault conditions needs to be estimated according to the fault type.

The calculation formulas of the residual service life of the sensor are as follows:

$$\{ \begin{matrix}L = \frac{{C}_{y}}{{k}_{v} {C}_{a}} \\ {k}_{v} = Co * {Ke}_{1}^{\frac{- Δ G}{RT}} * {K}_{Δ k} \\ {K}_{Δ k} = \frac{Δφ}{Δχ}\end{matrix} ,$$

where L represents the residual service life of the sensor, C_{y} represents the residual concentration of the electrolyte, Cₐ represents the initial concentration, kᵥ represents the reaction rate, Co represents dissolved oxygen concentration, K represents a pre-exponential factor of a chemical reaction, e₁ represents a constant, R represents a molar gas constant, T represents a reaction temperature, ΔG represents activation energy, K_{Δk} represents a fault reaction rate, Δφ represents an interval measurement difference, and Δχ represents a first threshold.

It should be noted that the smaller the L, the shorter the service life; the reaction rate kᵥ is related to the dissolved oxygen concentration Co, the reaction temperature T and the fault reaction rate K_{Δk}; the fault reaction rate K_{Δk} is related to the fault level. Under normal conditions, Δφ=Δχ, so that K_{Δk} is 1. Under fault conditions, K_{Δk} is the ratio of Δφ to Δχ.

According to the embodiment of the present disclosure, the residual service life of the sensor is determined based on the reaction rate, residual concentration and initial concentration of the electrolyte. Based on this, the residual service lives of the electrolyte and the sensor are estimated, which provides reference guidance for replacing the dissolved oxygen electrolyte in time and can improve the use safety of the sensor.

Based on the above embodiment, the target temperature is determined by the following steps: acquiring a temperature value of the sensor; acquiring the correlation information between the concentration and the impedance of the electrolyte based on the temperature value.

It should be noted that since the chemical reaction belongs to the system controlled by mixture of charge transfer and diffusion, it can be known from Arrhenius equation that the faradaic impedance has an inverse exponential relationship with temperature:

$$Z ∝ {Ke}_{1}^{\frac{Δ G}{RT}} ,$$

where Z represents an impedance, K represents a pre-exponential factor of a chemical reaction, e₁ represents a constant, R represents a molar gas constant, T represents a reaction temperature, and ΔG represents activation energy.

Therefore, it is necessary to construct a temperature compensation curve, in which the temperature compensation method is as follows: the relationship curves between the concentration and the impedance of the electrolyte at multiple temperatures is established by measuring the impedance and the solution concentration value at different temperatures, and the appropriate relationship curve at the corresponding temperature is selected according to the temperature measuring unit of the sensor itself, thereby realizing the temperature compensation. It can be understood that since the temperature will affect the impedance measurement of the electrolyte, in order to reduce the impedance measurement error, it is necessary to calibrate the temperature.

The temperature value of the sensor is acquired, and then the correlation information between the concentration and the impedance of the electrolyte is acquired based on the temperature value, that is, the correlation information between the concentration and the impedance of the electrolyte corresponding to the temperature value is acquired. For example, the relationship curves at different temperatures (such as 10° C., 20° C., 30° C. and 35° C.) is established, that is, the relationship curve between the concentration and the impedance of the electrolyte, and then the closest temperature curve parameter is selected for compensation calibration. For example, when the measurement temperature is 25° C., the relationship curve parameter of 25° C. is selected, that is, the relationship curve parameter between the concentration and the impedance of the electrolyte corresponding to 25° C. is selected. When the measuring temperature is 29° C., the relationship curve parameter of 30° C. is selected, that is, the relationship curve parameter between the concentration and the impedance of the electrolyte corresponding to 30° C. is selected.

According to the embodiment of the present disclosure, through the temperature compensation, the impedance measurement error is reduced such that the accuracy of impedance measurement is improved, and the accuracy of sensor fault diagnosis is further improved.

Based on the above embodiment, the method further includes: determining a sum value between the difference and a measurement error; and calibrating the sensor based on the difference if the sum value is greater than a tolerance deviation value and less than the first threshold value.

It should be noted that in the process of fault diagnosis, the signal drift resulted from electrode scaling can be self-compensated and calibrated. The surface of the electrode will be attached by the generated AgCl during the long-term measurement of dissolved oxygen for the electrode of the sensor itself is adopted, which causes signal drift in the results of dissolved oxygen measurement and alternating current impedance measurement. Based on the theoretical calculation value and the actual measurement value, the drift is compensated regularly, thereby effectively eliminating the signal drift resulted from electrode scaling and realizing self-calibration.

A sum value between the difference and a measurement error is determined; if the sum value is greater than a tolerance deviation value and less than the first threshold value, the sensor is calibrated based on the difference. For example, under normal conditions, the sensor is self-calibrated every two weeks (which can be determined based on the demand). According to the difference between the calculation value α and the measurement value β, the theoretical tolerance deviation value is Δγ in the case of considering the measurement error Δζ. If Δγ<|α−β+Δζ|<Δχ, the sensor electrode scaling error is calibrated and compensated according to the theoretical calculation value, that is, the calculation value α−β is used as the calibrated compensation parameters.

According to the embodiment of the present disclosure, the electrode scaling compensation function is performed, so that the influence of large errors resulted from electrode scaling drift is effectively reduced, thereby improving the accuracy of sensor fault diagnosis.

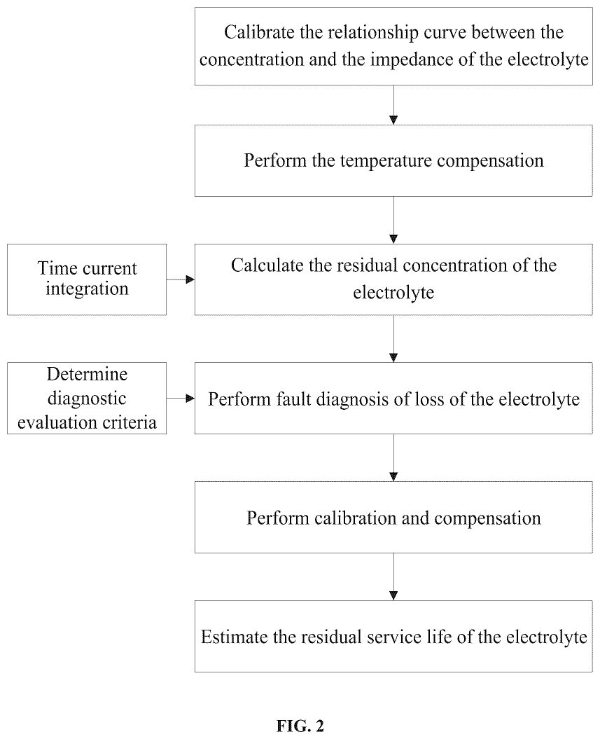

Referring to FIG. 2, it is a second schematic flow diagram of a sensor fault diagnosis method according to the present disclosure.

The embodiment of the present disclosure provides a method for self-diagnosis, self-calibration and life prediction of electrolyte in a dissolved oxygen sensor, which includes steps 1-6.

Step 1: The relationship curve between the concentration and the impedance of the electrolyte is calibrated.

It can be known from the reaction equation of a polarographic dissolved oxygen sensor that the reaction will consume chloride ions and water. According to the reaction equation, the corresponding impedances at different concentrations and volumes are measured, respectively. The relationship curve between the residual concentration C_{y} and the impedance Z of the electrolyte is established: Z∝C_{y}.

The reaction equation is as follows:

O₂+H₂O+4Ag+4KCl→4AgCl+4KOH,

where O₂ represents oxygen, H₂O represents water molecules, Ag represents silver, KCl represents potassium chloride, AgCl represents silver chloride, and KOH represents potassium hydroxide.

Step 2: The temperature compensation is performed.

Since the chemical reaction belongs to the system controlled by mixture of charge transfer and diffusion, it can be known from Arrhenius equation that the faradaic impedance has an inverse exponential relationship with temperature:

$$Z ∝ {Ke}_{1}^{\frac{Δ G}{RT}} ,$$

where Z represents an impedance, K represents a pre-exponential factor of a chemical reaction, e₁ represents a constant, R represents a molar gas constant, T represents a reaction temperature, and ΔG represents activation energy.

Therefore, it is necessary to construct a temperature compensation curve, in which the temperature compensation method is as follows: the relationship between the concentration and the impedance of the electrolyte at multiple temperatures is established by measuring the impedance and the solution concentration values at different temperatures, and the appropriate temperature curve at the corresponding temperature is selected according to the temperature measuring unit of the sensor itself, thereby realizing the temperature compensation.

Step 3: The residual concentration of the electrolyte is calculated.

The residual concentration of the electrolyte is related to the degree of chemical reaction. It can be known according to the chemical reaction equation that the number of reaction electrons is equal to the number of consumed chloride ions, and the reaction consumes water molecules. The residual concentration of the electrolyte can be derived from the current value, and the calculation formulas are as follows:

$$\{ \begin{matrix}N = \int \frac{1}{e} \cdot {I}_{t} \cdot dt \\ {C}_{y} = {C}_{a} - {C}_{b} = {C}_{a} - \frac{{C}_{a} \cdot {V}_{a} - N}{{V}_{a} - \frac{N \cdot M}{2 ρ}}\end{matrix} ,$$

where N represents the total number of electrons in the reaction system, e represents an elementary charge, Iₜ represents the current value at time t, C_{y} represents the residual concentration of the electrolyte, Cₐ represents the initial concentration, C_{b} represents the target concentration of the electrolyte at time t, Vₐ represents the initial volume of the electrolyte, M represents the molar mass of water, and ρ represents the density of water.

Step 4: Fault diagnosis of loss of the electrolyte is performed.

Under normal working conditions, the concentration of the electrolyte is related to the degree of reaction. When the solution membrane of the sensor is damaged or the sensor housing is broken, the electrolyte will be lost. The loss of electrolyte solution varies with the degree of damage. If the damage is serious, the electrolyte solution will be lost rapidly, and the impedance of the electrolyte will suddenly increase or decrease. If the damage is not serious, the impedance of the electrolyte will tend to increase or decrease rapidly in a period of time. Based on this, the electrolyte solution loss can be qualitatively analyzed by comparing the difference between the theoretical calculation value and the measurement value of the electrolyte.

Under normal conditions, the absolute value of the difference between the theoretical calculation value α and the measurement value β of the electrolyte is less than Δχ. If the situation is not satisfied, it is determined that the sensor has a fault, and then the interval measurement is carried out for three times. If the interval measurement difference Δp is greater than Δq, it is determined that the electrolyte has a fault of complete loss. If the interval measurement difference is greater than Δy and less than Δq, it is determined that the electrolyte has a fault of serious loss. If the interval measurement difference is greater than Δz and less than Δy, it is determined that the electrolyte has a fault of slow loss.

Step 5: Calibration and compensation are performed.

Under normal conditions, the sensor is self-calibrated every two weeks (which can be determined based on the demand). According to the difference between the calculation value α and the measurement value β, the theoretical tolerance deviation value is Δγ in the case of considering the measurement error Δζ. If Δγ<|α−β+Δζ|<Δχ, the sensor electrode scaling error is calibrated and compensated according to the theoretical calculation value, that is, the calculation value α−β is used as the calibrated compensation parameters.

Step 6: The residual service life of the electrolyte is estimated.

Under normal working conditions, the residual service life of the electrolyte is related to the degree of reaction, and the service life under fault conditions needs to be estimated according to the fault type.

The calculation formulas of the residual service life of the sensor are as follows:

$$\{ \begin{matrix}L = \frac{{C}_{y}}{{k}_{v} {C}_{a}} \\ {k}_{v} = Co * {Ke}_{1}^{\frac{- Δ G}{RT}} * {K}_{Δ k} \\ {K}_{Δ k} = \frac{Δφ}{Δχ}\end{matrix} ,$$

where L represents the residual service life of the sensor, C_{y} represents the residual concentration of the electrolyte, Cₐ represents the initial concentration, kᵥ represents a reaction rate, Co represents dissolved oxygen concentration, K represents a pre-exponential factor of a chemical reaction, e₁ represents a constant, R represents a molar gas constant, T represents a reaction temperature, ΔG represents activation energy, K_{Δk} represents a fault reaction rate, Δφ represents an interval measurement difference, and Δχ represents a first threshold.

According to the embodiment of the present disclosure, the fault diagnosis, self-calibration and life prediction of the electrolyte in the dissolved oxygen sensor are realized by taking the measurement signal as the basis in combination with theoretical calculation, which and has the following advantages:
(1) The diagnosis and classification of electrolyte loss fault is realized, by estimating the concentration of the electrolyte according to an impedance calibrating method in combination with theoretical calculation, and establishing a difference comparison interval.
(2) Based on the original electrode structure, the impedance can be measured without adding other impedance measuring units or modifying the sensor elements.
(3) The present disclosure has the functions of temperature compensation and electrode scaling compensation, effectively reducing the error influence resulted from temperature and electrode scaling drift.
(4) The residual service life of the electrolyte is estimated, and reference guidance is provided for replacing the dissolved oxygen electrolyte in time.

Based on the above embodiments, the embodiment of the present disclosure further provides a sensor fault diagnosis apparatus, which is applied to the above embodiments. The apparatus includes a channel switching circuit 9, a current to voltage measuring module 10 and an impedance measuring module 12.

The channel switching circuit 9 is configured to control switching the current to voltage acquisition module and the impedance measuring module.

The current to voltage measuring module 10 is configured to measure a current value corresponding to dissolved oxygen in the electrolyte.

The impedance measuring module 12 is configured to measure an impedance value of the electrolyte.

It should be noted that in the embodiment of the present disclosure, the alternating current impedance of the solution is measured by directly applying a small amplitude of alternating voltage to a polarographic dissolved oxygen electrode, which can effectively prevent electrode polarization and avoid hardware redundancy resulted from adding other impedance measuring electrodes or sensors.

Further, the embodiment of the present disclosure uses a multiplexed self-switching signal acquisition system, namely current measurements and impedance measurements. The multiplexed switching is controlled by a microprocessor, and the microprocessor controls the converter to automatically switch between a dissolved oxygen direct current signal measurement circuit and an alternating current signal diagnosis circuit according to the working hours of the sensor.

As shown in FIG. 3, the sensor fault diagnosis apparatus includes a probe housing 1, a silver wire 2, electrolyte 3, a platinum wire 4, environmental solution 5, an environmental solution boundary 6, a dissolved oxygen permeable membrane 7, a temperature detection module 8, a channel switching circuit 9, a current to voltage measuring module 10, a microprocessor 11, an impedance measuring module 12 and a power supply 13.

It should be noted that the electrolyte 3 can be KCl electrolyte or KCl/KOH electrolyte; the platinum wire 4 can be replaced by a gold wire; the dissolved oxygen permeable membrane 7 includes but is not limited to a polyethylene membrane, a polytetrafluoroethylene membrane, a perfluoroethylene propylene membrane, a polydimethylsiloxane membrane and a polytetrafluoroethylene/silica composite membrane; and the current to voltage measuring module 10 includes an analog-to-digital conversion function.

As shown in FIG. 3, the embodiment of the present disclosure uses a two-electrode polarographic dissolved oxygen sensor probe, in which the temperature detection module 8 is built. The channel switching circuit 9 and the impedance measuring module 12, in addition to the current to voltage measuring module 10, are added in the signal acquisition circuit. The electrodes in the embodiment of the present disclosure serve as both the reaction electrodes for dissolved oxygen detection and the support electrodes for solution impedance detection, and the electrode multiplexing function is realized by the channel switching circuit 9.

The microprocessor 11 realizes the circuit selection between the current to voltage measuring module 10 and the impedance measuring module 12 by controlling the channel switching circuit 9. When the circuit is switched to the current to voltage measuring module 10, the electrodes 2 and 4 can be used to measure the dissolved oxygen current to acquire the dissolved oxygen value. When the circuit is switched to the impedance measuring module 12, the electrodes can be used to detect the impedance of the electrolyte 3 to acquire the concentration value of the electrolyte.

It can be understood that after the dissolved oxygen current is measured by the current to voltage measuring module 10, the microprocessor 11 can determine the total number of electrons in the reaction system based on the current, then determine the target concentration of the electrolyte in the sensor at time t based on the total number of electrons, the initial concentration, the initial volume of the electrolyte, the molar mass of water and the density of water, and finally determine the residual concentration of the electrolyte based on the target concentration and the initial concentration.

After the impedance value of the electrolyte is measured by the impedance measuring module 12, the microprocessor 11 determines the concentration measurement value of the electrolyte based on the correlation information between the concentration and the impedance of the electrolyte and the measured impedance value.

Finally, the microprocessor 11 determines the fault information of the sensor based on the residual concentration and the concentration measurement value of the electrolyte.

According to the sensor fault diagnosis apparatus provided by the embodiment of the present disclosure, the concentration of the electrolyte is estimated by using an impedance calibrating method in combination with theoretical calculation, and the sensor fault diagnosis is realized by establishing a difference comparison interval between the concentration measurement value and a theoretical calculation value of the electrolyte, so that the cost of fault diagnosis is saved and the accuracy of fault diagnosis is improved.

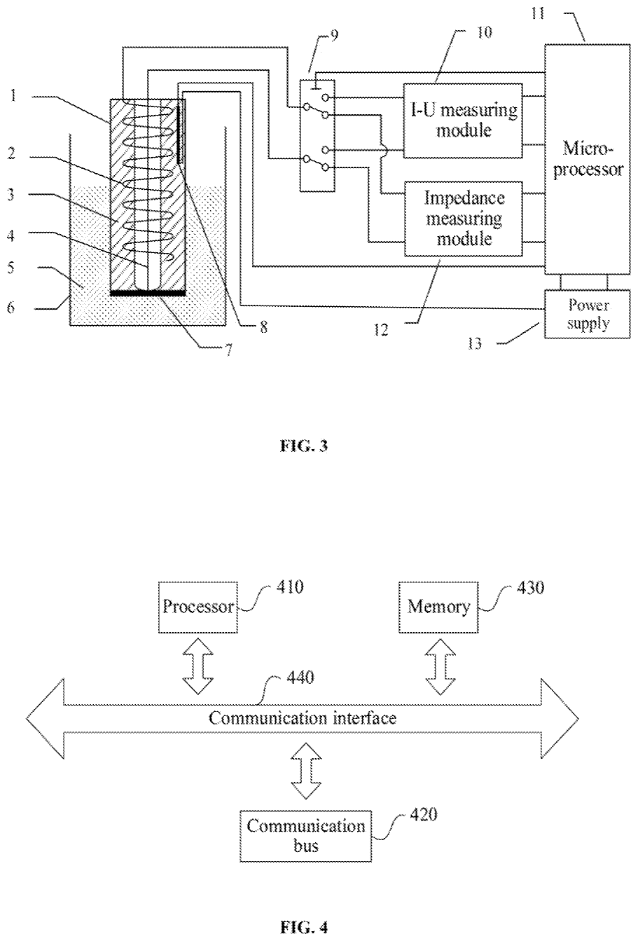

FIG. 4 illustrates a schematic structural diagram of an electronic device. As shown in FIG. 4, the electronic device may include a processor 410, a communication interface 420, a memory 430 and a communication bus 440, wherein the processor 410, the communication interface 420 and the memory 430 communicate with each other through the communication bus 440. The processor 410 may call logic instructions in the memory 430 to perform a sensor fault diagnosis method, wherein the method includes:
determining target concentration of electrolyte in a sensor at time t;
determining residual concentration of the electrolyte based on initial concentration and the target concentration of the electrolyte;
acquiring an impedance value of the electrolyte and determining a concentration measurement value of the electrolyte based on the impedance value and correlation information between the concentration and the impedance of the electrolyte;
determining fault information of the sensor based on the residual concentration and the concentration measurement value of the electrolyte.

In addition, the above-mentioned logical instructions in the memory 440 can be realized in the form of software functional units and can be stored in a computer-readable storage medium when they are sold or used as independent products. Based on this understanding, the technical solution of the present disclosure in essence or the part thereof that contributes to the prior art, can be embodied in the form of a software product. The computer software product is stored in a storage medium, including several instructions so that a computer device (which can be a personal computer, a server, a network device, etc.) executes all or part of the steps of the method described in various embodiments of the present disclosure. The aforementioned storage media includes various media that can store program codes, such as a U disk, a mobile hard disk, a Read-Only Memory (ROM), a Random Access Memory (RAM), a magnetic disk or an optical disk.

On the other hand, the present disclosure further provides a non-transient computer-readable storage medium on which a computer program is stored, wherein the computer program, when executed by a processor, performs the sensor fault diagnosis method provided by the above methods, wherein the method includes:
determining target concentration of electrolyte in a sensor at time t;
determining residual concentration of the electrolyte based on initial concentration and the target concentration of the electrolyte;
acquiring an impedance value of the electrolyte and determining a concentration measurement value of the electrolyte based on the impedance value and correlation information between the concentration and the impedance of the electrolyte;
determining fault information of the sensor based on the residual concentration and the concentration measurement value of the electrolyte.

The apparatus embodiments described above are only schematic, in which the units described as separate components may or may not be physically separated, and the components displayed as units may or may not be physical units, that is, they may be located in one place or distributed to a plurality of network units. Some or all of the modules can be selected according to actual requirements to achieve the purpose of this embodiment. Those skilled in the art can understand and implement the apparatus embodiments without creative efforts.

From the description of the above embodiments, those skilled in the art can clearly understand that each embodiment can be realized by means of software plus a necessary general hardware platform, and of course each embodiment can also be realized by hardware. Based on this understanding, the above technical solution in essence or the part thereof that contributes to the prior art, can be embodied in the form of a software product. The computer software product can be stored in a computer-readable storage medium, such as an ROM/RAM, a magnetic disk, an optical disk, etc., including several instructions so that a computer device (which can be a personal computer, a server, a network device, etc.) executes the method described in various embodiments or some parts of the embodiments.

Finally, it should be noted that the above embodiments are only used to illustrate the technical solution of the present disclosure, rather than limit the technical solution. Although the present disclosure has been described in detail with reference to the foregoing embodiments, those skilled in the art should understand that it is still possible to modify the technical solution described in the foregoing embodiments or make equivalent substitutions to some technical features.

However, these modifications or substitutions do not make the essence of the corresponding technical solutions deviate from the spirit and scope of the technical solutions of various embodiments of the present disclosure.

What is claimed is:

1. A sensor fault diagnosis method, comprising:
determining target concentration of electrolyte in a sensor at time t;
determining residual concentration of the electrolyte based on initial concentration and the target concentration of the electrolyte;
acquiring an impedance value of the electrolyte, and determining a concentration measurement value of the electrolyte based on the impedance value and correlation information between concentration and an impedance of the electrolyte; and
determining fault information of the sensor based on the residual concentration and the concentration measurement value of the electrolyte.

2. The sensor fault diagnosis method according to claim 1, wherein determining the fault information of the sensor based on the residual concentration and the concentration measurement value of the electrolyte comprises:
determining a difference between the residual concentration and the concentration measurement value of the electrolyte;
determining that the sensor has a fault when the difference is greater than a first threshold value; and
determining an interval measurement difference of the concentration of the electrolyte and determining a fault level of the sensor based on the interval measurement difference.

3. The sensor fault diagnosis method according to claim 2, wherein determining the fault level of the sensor based on the interval measurement difference comprises:
determining that the fault level of the sensor is level 1 when the interval measurement difference is greater than a second threshold;
determining that the fault level of the sensor is level 2 when the interval measurement difference is greater than a third threshold and less than the second threshold; and
determining that the fault level of the sensor is level 3 when the interval measurement difference is greater than a fourth threshold and less than the third threshold.

4. The sensor fault diagnosis method according to claim 1, wherein determining the target concentration of the electrolyte in the sensor at time t comprises:
determining a total number of electrons in a reaction system corresponding to the electrolyte; and
determining the target concentration of the electrolyte in the sensor at time t based on the total number of electrons, the initial concentration, initial volume of the electrolyte, molar mass of water and density of water,
wherein calculation formulas of the target concentration of the electrolyte in the sensor at time t are as follows:
$$\{ \begin{matrix}N = \int \frac{1}{e} . {I}_{t} . dt \\ {C}_{b} = \frac{{C}_{a} . {V}_{a} - N}{{V}_{a} - \frac{N . M}{2 ρ}}\end{matrix} ,$$
where N represents the total number of electrons in the reaction system, e represents an elementary charge, Iₜ represents a current value at time t, Cₐ represents the initial concentration, C_{b} represents the target concentration of the electrolyte at time t, Vₐ represents the initial volume of the electrolyte, M represents the molar mass of water, and ρ represents the density of water.

5. The sensor fault diagnosis method according to claim 1, wherein, after determining the residual concentration of the electrolyte based on the initial concentration and the target concentration of the electrolyte, the method further comprises:
determining a reaction rate of the electrolyte; and
determining a residual service life of the sensor based on the reaction rate, the residual concentration and the initial concentration of the electrolyte,
wherein calculation formulas of the residual service life of the sensor are as follows:
$$\{ \begin{matrix}L = \frac{{C}_{y}}{{k}_{v} {C}_{a}} \\ {k}_{v} = Co * {Ke}_{1}^{\frac{- Δ G}{RT}} * {K}_{Δ k} \\ {K}_{Δ k} = \frac{Δφ}{Δχ}\end{matrix} ,$$
where L represents the residual service life of the sensor, C_{y} represents the residual concentration of the electrolyte, Cₐ represents the initial concentration, kᵥ represents the reaction rate, Co represents dissolved oxygen concentration, K represents a pre-exponential factor of a chemical reaction, e₁ represents a constant, R represents a molar gas constant, T represents a reaction temperature, ΔG represents activation energy, K_{Δk} represents a fault reaction rate, Δφ represents an interval measurement difference, and Δχ represents a first threshold.

6. The sensor fault diagnosis method according to claim 1, wherein before determining the concentration measurement value of the electrolyte based on the impedance value and the correlation information between the concentration and the impedance of the electrolyte, the method further comprises:
acquiring a temperature value of the sensor; and
acquiring the correlation information between the concentration and the impedance of the electrolyte based on the temperature value.

7. The sensor fault diagnosis method according to claim 2, wherein the method further comprises:
determining a sum value between the difference and a measurement error; and
calibrating the sensor based on the difference when the sum value is greater than a tolerance deviation value and less than the first threshold value.

8. A sensor fault diagnosis apparatus, applied to the sensor fault diagnosis method according to claim 1, wherein, the sensor fault diagnosis apparatus comprises: a channel switching circuit, a current to voltage measuring module and an impedance measuring module;
wherein the channel switching circuit is configured to control switching the current to voltage acquisition module and the impedance measuring module;
the current to voltage measuring module is configured to measure a current value corresponding to dissolved oxygen in the electrolyte; and
the impedance measuring module is configured to measure the impedance value of the electrolyte.

9. The sensor fault diagnosis apparatus according to claim 8, wherein determining the fault information of the sensor based on the residual concentration and the concentration measurement value of the electrolyte comprises:
determining a difference between the residual concentration and the concentration measurement value of the electrolyte;
determining that the sensor has a fault when the difference is greater than a first threshold value; and
determining an interval measurement difference of the concentration of the electrolyte and determining a fault level of the sensor based on the interval measurement difference.

10. The sensor fault diagnosis apparatus according to claim 9, wherein determining the fault level of the sensor based on the interval measurement difference comprises:
determining that the fault level of the sensor is level 1 when the interval measurement difference is greater than a second threshold;
determining that the fault level of the sensor is level 2 when the interval measurement difference is greater than a third threshold and less than the second threshold; and
determining that the fault level of the sensor is level 3 when the interval measurement difference is greater than a fourth threshold and less than the third threshold.

11. The sensor fault diagnosis apparatus according to claim 8, wherein determining the target concentration of the electrolyte in the sensor at time t comprises:
determining a total number of electrons in a reaction system corresponding to the electrolyte; and
determining the target concentration of the electrolyte in the sensor at time t based on the total number of electrons, the initial concentration, initial volume of the electrolyte, molar mass of water and density of water,
wherein calculation formulas of the target concentration of the electrolyte in the sensor at time t are as follows:
$$\{ \begin{matrix}N = \int \frac{1}{e} . {I}_{t} . dt \\ {C}_{b} = \frac{{C}_{a} . {V}_{a} - N}{{V}_{a} - \frac{N . M}{2 ρ}}\end{matrix} ,$$
where N represents the total number of electrons in the reaction system, e represents an elementary charge, Iₜ represents a current value at time t, Cₐ represents the initial concentration, C_{b} represents the target concentration of the electrolyte at time t, Vₐ represents the initial volume of the electrolyte, M represents the molar mass of water, and ρ represents the density of water.

12. The sensor fault diagnosis apparatus according to claim 8, wherein, after determining the residual concentration of the electrolyte based on the initial concentration and the target concentration of the electrolyte, the method further comprises:
determining a reaction rate of the electrolyte; and
determining a residual service life of the sensor based on the reaction rate, the residual concentration and the initial concentration of the electrolyte,
wherein calculation formulas of the residual service life of the sensor are as follows:
$$\{ \begin{matrix}L = \frac{{C}_{y}}{{k}_{v} {C}_{a}} \\ {k}_{v} = Co * {Ke}_{1}^{\frac{- Δ G}{RT}} * {K}_{Δ k} \\ {K}_{Δ k} = \frac{Δφ}{Δχ}\end{matrix} ,$$
where L represents the residual service life of the sensor, C_{y} represents the residual concentration of the electrolyte, Cₐ represents the initial concentration, kᵥ represents the reaction rate, Co represents dissolved oxygen concentration, K represents a pre-exponential factor of a chemical reaction, e₁ represents a constant, R represents a molar gas constant, T represents a reaction temperature, ΔG represents activation energy, K_{Δk} represents a fault reaction rate, Δφ represents an interval measurement difference, and Δχ represents a first threshold.

13. An electronic device, comprising a memory, a processor and a computer program stored in the memory and executable on the processor, wherein the processor, when executing the computer program, implements the sensor fault diagnosis method according to claim 1.

14. The electronic device according to claim 13, wherein determining the fault information of the sensor based on the residual concentration and the concentration measurement value of the electrolyte comprises:
determining a difference between the residual concentration and the concentration measurement value of the electrolyte;
determining that the sensor has a fault when the difference is greater than a first threshold value; and
determining an interval measurement difference of the concentration of the electrolyte and determining a fault level of the sensor based on the interval measurement difference.

15. The electronic device according to claim 14, wherein determining the fault level of the sensor based on the interval measurement difference comprises:
determining that the fault level of the sensor is level 1 when the interval measurement difference is greater than a second threshold;
determining that the fault level of the sensor is level 2 when the interval measurement difference is greater than a third threshold and less than the second threshold; and
determining that the fault level of the sensor is level 3 when the interval measurement difference is greater than a fourth threshold and less than the third threshold.

16. The electronic device according to claim 13, wherein determining the target concentration of the electrolyte in the sensor at time t comprises:
determining a total number of electrons in a reaction system corresponding to the electrolyte; and
determining the target concentration of the electrolyte in the sensor at time t based on the total number of electrons, the initial concentration, initial volume of the electrolyte, molar mass of water and density of water,
wherein calculation formulas of the target concentration of the electrolyte in the sensor at time t are as follows:
$$\{ \begin{matrix}N = \int \frac{1}{e} . {I}_{t} . dt \\ {C}_{b} = \frac{{C}_{a} . {V}_{a} - N}{{V}_{a} - \frac{N . M}{2 ρ}}\end{matrix} ,$$
where N represents the total number of electrons in the reaction system, e represents an elementary charge, Iₜ represents a current value at time t, Cₐ represents the initial concentration, C_{b} represents the target concentration of the electrolyte at time t, Vₐ represents the initial volume of the electrolyte, M represents the molar mass of water, and ρ represents the density of water.

17. A non-transient computer-readable storage medium on which a computer program is stored, wherein the computer program, when executed by a processor, implements the sensor fault diagnosis method according to claim 1.

18. The non-transient computer-readable storage medium according to claim 17, wherein determining the fault information of the sensor based on the residual concentration and the concentration measurement value of the electrolyte comprises:
determining a difference between the residual concentration and the concentration measurement value of the electrolyte;
determining that the sensor has a fault when the difference is greater than a first threshold value; and
determining an interval measurement difference of the concentration of the electrolyte and determining a fault level of the sensor based on the interval measurement difference.

19. The non-transient computer-readable storage medium according to claim 18, wherein determining the fault level of the sensor based on the interval measurement difference comprises:
determining that the fault level of the sensor is level 1 when the interval measurement difference is greater than a second threshold;
determining that the fault level of the sensor is level 2 when the interval measurement difference is greater than a third threshold and less than the second threshold; and
determining that the fault level of the sensor is level 3 when the interval measurement difference is greater than a fourth threshold and less than the third threshold.

20. The non-transient computer-readable storage medium according to claim 17, wherein determining the target concentration of the electrolyte in the sensor at time t comprises:
determining a total number of electrons in a reaction system corresponding to the electrolyte; and
determining the target concentration of the electrolyte in the sensor at time t based on the total number of electrons, the initial concentration, initial volume of the electrolyte, molar mass of water and density of water,
wherein calculation formulas of the target concentration of the electrolyte in the sensor at time t are as follows:
$$\{ \begin{matrix}N = \int \frac{1}{e} . {I}_{t} . dt \\ {C}_{b} = \frac{{C}_{a} . {V}_{a} - N}{{V}_{a} - \frac{N . M}{2 ρ}}\end{matrix} ,$$
where N represents the total number of electrons in the reaction system, e represents an elementary charge, Iₜ represents a current value at time t, Cₐ represents the initial concentration, C_{b} represents the target concentration of the electrolyte at time t, Vₐ represents the initial volume of the electrolyte, M represents the molar mass of water, and ρ represents the density of water.
